(19) United States
(12) Patent Application Publication
(10) Pub. No.: US 2005/0176224 A1
(43) Pub. Date: Aug. 11, 2005

(54) Ion implantation method in semiconductor device

(75) Inventors: Kim Dae Kyeun, Yongin (KR); Jung Myung Jin, Seoul (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Seoul (KR)

(21) Appl. No.: 11/024,704

(22) Filed: Dec. 30, 2004

(30) Foreign Application Priority Data
Dec. 30, 2003 (KR) 10-2003-0100526

(51) Int. Cl. H01L 21/8238; H01L 21/425

(52) U.S. Cl. 438/514; 438/531

(57) ABSTRACT

An ion implantation method in a semiconductor device, by which performance of the semiconductor device can be enhanced by defining a stable ion implantation area in a manner of improving an edge profile of an ion implantation mask to enhance performance of the semiconductor device. The present invention includes the steps of coating a mask material on a semiconductor substrate, patterning the mask material to form an ion implantation mask exposing an ion implantation area of the semiconductor substrate, transforming an edge profile of the ion implantation mask into a round pattern from a sharp pattern, and implanting ions into the exposed ion implantation area of the semiconductor substrate using the transformed ion implantation mask.

### BACKGROUND OF THE INVENTION

1. Field of the Invention

The present invention relates to a method of fabricating a semiconductor device, and more particularly, to an ion implantation method in a semiconductor device.

2. Discussion of the Related Art

First of all, an ion implantation method according to a related art is explained as follows.

FIGS. 1A to 1C are cross-sectional diagrams for explaining an ion implantation method according to a related art.

Referring to FIG. 1A, a thin oxide layer 13 is formed on a semiconductor substrate 111 as a sacrifice layer 13 preventing the semiconductor substrate 11 from being damaged by ion implantation.

Photoresist is then coated on the sacrifice layer 13 to form a photoresist layer 15 that will be used as an ion implantation mask.

Referring to FIG. 1B, the photoresist layer 15 is patterned to form a photoresist pattern 15 exposing an ion implantation area over the semiconductor substrate 11.

Referring to FIG. 1C, tilt and twist ion implantation is carried out on the semiconductor substrate 11 using the photoresist pattern 15 as the ion implantation mask, whereby ions are implanted into a portion of the semiconductor substrate in the exposed ion implantation area.

However, in the related art ion implantation method, a shadow effect takes place since the photoresist pattern used as the ion implantation mask has a vertical edge profile. Specifically, edge portions A, as shown in FIG. 1C, of the substrate in the ion implantation area are blocked by the ion implantation mask, whereby it is unable to normally implant the ions into the edge portions A of the semiconductor substrate.

Hence, performance of the semiconductor device is degraded since the ion implantation area fails to be stably defined.

### SUMMARY OF THE INVENTION

Accordingly, the present invention is directed to an ion implantation method in a semiconductor device that substantially obviates one or more problems due to limitations and disadvantages of the related art.

The present invention advantageously provides an ion implantation method in a semiconductor device, by which performance of the semiconductor device can be enhanced by defining a stable ion implantation area in a manner of improving an edge profile of an ion implantation mask to enhance performance of the semiconductor device.

Additional advantages, objects, and features of the invention will be set forth in part in the description which follows and in part will become apparent to those having ordinary skill in the art upon examination of the following. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, an ion implantation method in a semiconductor device according to the present invention includes the steps of coating a mask material on a semiconductor substrate, patterning the mask material to form an ion implantation mask exposing an ion implantation area of the semiconductor substrate, transforming an edge profile of the ion implantation mask into a round pattern from a sharp pattern, and implanting ions into the exposed ion implantation area of the semiconductor substrate using the transformed ion implantation mask.

Preferably, the ion implantation method further includes the step of forming a sacrifice layer on the substrate prior to the coating step.

Preferably, the mask material is photoresist and the ion implantation mask is a photoresist pattern.

More preferably, the edge profile of the photoresist pattern is transformed into the round pattern by carrying out flowing on the photoresist pattern.

More preferably, the flowing is carried out by thermal treatment.

More preferably, the flowing is carried out by rapid thermal processing.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1A to 1C are cross-sectional diagrams for explaining an ion implantation method according to a related art; and

FIGS. 2A to 2D are cross-sectional diagrams for explaining an ion implantation method according to the present invention.

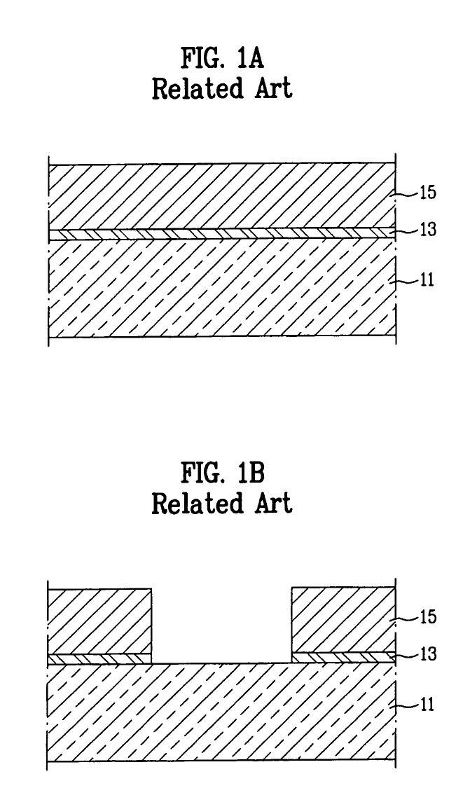

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

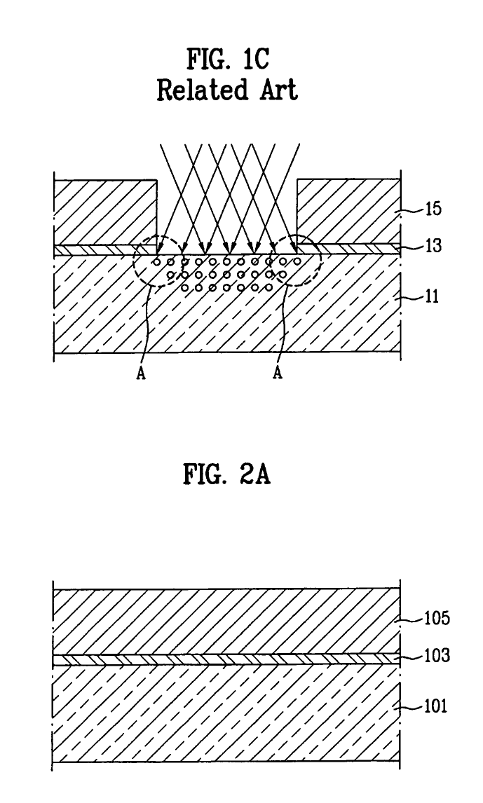

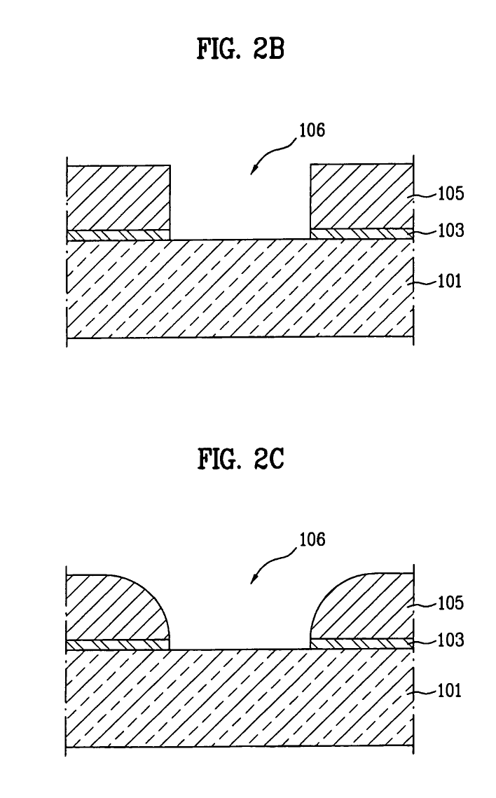

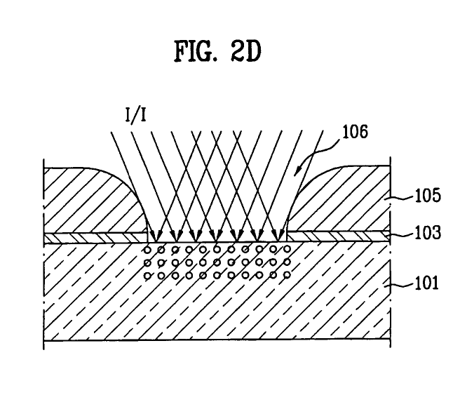

FIGS. 2A to 2D are cross-sectional diagrams for explaining an ion implantation method according to the present invention.

Referring to FIG. 2A, a thin oxide layer 103 is formed on a semiconductor substrate 101 as a sacrifice layer 103 preventing the semiconductor substrate 101 from being damaged by ion implantation.

Photoresist is then coated on the sacrifice layer 103 to form a photoresist layer 105 that will be used as an ion implantation mask.

Referring to FIG. 2B, the photoresist layer 105 is patterned to form a photoresist pattern 105 having an opening 106 that exposes an ion implantation area over the semiconductor substrate 101. In doing so, the photoresist layer 105 is patterned by exposure and development using a mask defining an ion implantation area, for example.

Referring to FIG. 2C, flowing is carried out on the photoresist pattern 105 by thermal treatment such as RTP (rapid thermal processing) and the like so that an edge profile of the photoresist pattern 105 defining the ion implantation area over the semiconductor substrate 101 can be transformed. In doing so, an upper edge part of the photoresist pattern 105, which is formed of a polymer material using phenol as a base material, in the vicinity of the opening 106 is transformed into a round pattern from a sharp pattern by the flowing using the thermal treatment. Hence, the edge profile of the photoresist pattern 105 can be provided with a specific profile in a manner of adjusting a thermal treatment temperature or a process time.

Referring to FIG. 2D, ion implantation I/I using tilt and twist is carried out on the exposed surface of the semiconductor substrate using the photoresist pattern 105, of which edge profile adjacent to the opening 106 is transformed into the round pattern, as an ion implantation mask.

In doing so, as a result of using the photoresist pattern 105 having the round edge profile as the ion implantation mask, the ion implantation area blocked by the ion implantation mask is minimized. Hence, the shadow effect can be minimized.

Accordingly, the present invention improves the edge profile of the ion implantation mask to form a stable ion implantation area, thereby enhancing performance of the semiconductor device.

Korean Application No. P2003-0100526 filed on Dec. 30, 2003, is hereby incorporated by reference in its entirety.

It will be apparent to those skilled in the art that various modifications and variations can be made in the present invention. Thus, it is intended that the present invention covers the modifications and variations of this invention provided they come within the scope of the appended claims and their equivalents.

1. An ion implantation method in a semiconductor device, comprising the steps of:
coating a mask material on a semiconductor substrate;
patterning the mask material to form an ion implantation mask exposing an ion implantation area of the semiconductor substrate;
transforming an edge profile of the ion implantation mask into a round pattern from a sharp pattern; and
implanting ions into the exposed ion implantation area of the semiconductor substrate using the transformed ion implantation mask.

2. The ion implantation method of claim 1, further comprising the step of forming a sacrifice layer on the substrate prior to the coating step.

3. The ion implantation method of claim 1, wherein the mask material is photoresist and wherein the ion implantation mask is a photoresist pattern.

4. The ion implantation method of claim 3, wherein the edge profile of the photoresist pattern is transformed into the round pattern by carrying out flowing on the photoresist pattern.

5. The ion implantation method of claim 4, wherein the flowing is carried out by thermal treatment.

6. The ion implantation method of claim 4, wherein the flowing is carried out by rapid thermal processing.

7. An ion implantation method in a semiconductor device, comprising:
a step for coating a mask material on a semiconductor substrate;
a step for patterning the mask material to form an ion implantation mask exposing an ion implantation area of the semiconductor substrate;
a step for transforming an edge profile of the ion implantation mask into a round pattern from a sharp pattern; and
a step for implanting ions into the exposed ion implantation area of the semiconductor substrate using the transformed ion implantation mask.

8. The ion implantation method of claim 7, further comprising a step for forming a sacrifice layer on the substrate prior to the coating step.

9. The ion implantation method of claim 7, wherein the mask material is photoresist and wherein the ion implantation mask is a photoresist pattern.

10. The ion implantation method of claim 9, wherein the edge profile of the photoresist pattern is transformed into the round pattern by carrying out flowing on the photoresist pattern.

11. The ion implantation method of claim 10, wherein the flowing is carried out by thermal treatment.

12. The ion implantation method of claim 10, wherein the flowing is carried out by rapid thermal processing.
